(19) United States
(12) Patent Application Publication
(10) Pub. No.: US 2026/0005598 A1
(43) Pub. Date: Jan. 1, 2026

(54) SEMICONDUCTOR DRIVING DEVICE AND POWER CONVERSION DEVICE

(71) Applicant: Mitsubishi Electric Corporation, Tokyo (JP)

(72) Inventor: Kohei ONDA, Tokyo (JP)

(73) Assignee: Mitsubishi Electric Corporation, Tokyo (JP)

(21) Appl. No.: 18/880,568

(22) PCT Filed: Jul. 11, 2022
(86) PCT No.: PCT/JP2022/027184

§ 371 Date: Jan. 2, 2025

(51) Int. Cl. H02M 1/088; H02M 3/335

(52) U.S. Cl. CPC H02M 1/088; H02M 3/33576

(57) ABSTRACT

A semiconductor driving device according to the present disclosure includes: a timing generation unit which generates gate ON reference signals respectively for a plurality of gate terminals; a gate reference waveform generation unit which generates a first gate reference waveform and a second gate reference waveform on the basis of the gate ON reference signals, and controls the first gate reference waveform and the second gate reference waveform in shifting from a non-conductive state to a conductive state of a multi-gate semiconductor switching element and shifting from a conductive state to a non-conductive state of the multi-gate semiconductor switching element; and a signal amplification unit which receives, as an input waveform, the first gate reference waveform and the second gate reference waveform, and amplifies the input waveform so that an output waveform follows the input waveform.

### TECHNICAL FIELD

The present disclosure relates to a semiconductor driving device and a power conversion device.

### BACKGROUND ART

As one of measures for global warming, expectation for energy saving by power electronics technology is increasing. In particular, for increasing efficiency of a power conversion device that uses ON/OFF operations of a plurality of semiconductor switching elements, it is required to reduce loss in the semiconductor switching elements composing the power conversion device.

Typical examples of semiconductor switching elements include semiconductor switching elements of a voltage driving type such as an insulated gate bipolar transistor (IGBT) and a metal-oxide-semiconductor field-effect transistor (MOSFET), and diodes provided in parallel to the semiconductor switching elements and serving for rectification.

As means for improvement in trade-off of conduction loss and switching loss of a semiconductor switching element, a double-gate semiconductor switching element having two independent gate terminals may be applied. The double-gate semiconductor switching element has a feature that, for example, in turn-off operation, control is performed so that one gate terminal is turned off sufficiently prior to the other gate terminal and then the other gate terminal is turned off. With this control method, turn-off operation is performed in a state in which some of carriers in the double-gate semiconductor switching element are extracted in advance, and thus a carrier extraction period can be shortened, whereby turn-off loss can be reduced.

A time difference between ON/OFF operations of both gate terminals may be set to be short so that a timing when one gate terminal is turned on/off after the other gate terminal is turned on/off becomes within a switching operation period, whereby it is possible to obtain an effect of transiently making switching characteristics variable, i.e., an active gate effect.

For example, an active gate effect of a single-gate semiconductor switching element can be obtained by a method of switching the gate resistance during a turn-on operation period. It is known that, by applying this switchover method, a trade-off relationship between turn-on loss of the semiconductor switching element and a recovery voltage change rate dV/dt of a diode of an opposite arm is improved. In this regard, in a double-gate semiconductor switching element, an effect similar to the above switchover method can be obtained through driving with a time difference between two gate terminals.

As a method of driving with a time difference given between two gate terminals of a double-gate semiconductor switching element, for example, in a semiconductor device and a semiconductor device control method disclosed in Patent Document 1, the following configuration is shown. The semiconductor device includes a delay unit which delays a signal inputted to a control signal input terminal by a delay period L, and a logical conjunction unit which performs logical conjunction of the signal inputted to the control signal input terminal and the signal delayed by the delay unit, and an output of the delay unit and an output of the logical conjunction unit are respectively connected to two gate terminals of a double-gate IGBT. In the configuration of the semiconductor device disclosed in Patent Document 1, if a time difference between voltage waveforms to be given to the two gate terminals is set to be short, the above active gate effect can be obtained.

In a semiconductor device and a semiconductor device driving method described in Patent Document 2, the following method is disclosed. In shifting from a non-conductive state to a conductive state of a double-gate IGBT, voltage not less than threshold voltage is applied to a first gate terminal prior to a second gate terminal by a first predetermined period, and in shifting from a conductive state to a non-conductive state, voltage less than the threshold voltage is applied to the second gate terminal prior to the first gate terminal by a second predetermined period. Then, the first predetermined period and the second predetermined period are variably controlled so that temporal change in collector voltage that occurs in shifting from a non-conductive state to a conductive state and shifting from a conductive state to a non-conductive state becomes substantially constant.

In the above configuration, in a case where a time difference between voltage waveforms given to the two gate electrodes is set to be short, it is possible to improve robustness against a voltage change rate dV/dt due to noise, load current based on surge voltage, a temperature, and the like by changing the time difference between the voltage waveforms.

### CITATION LIST

### Patent Document

Patent Document 1: Japanese Laid-Open Patent Publication No. 2019-103286
Patent Document 2: Japanese Laid-Open Patent Publication No. 2020-162022

### SUMMARY OF THE INVENTION

### Problem to be Solved by the Invention

However, for example, in the semiconductor device and the semiconductor device control method described in Patent Document 1, in the case of obtaining the above active gate effect by setting the time difference to be short so that the timing of turning on/off one gate terminal of the double-gate IGBT after turning on/off the other gate terminal becomes within the switching operation period, the delayed control signal input terminal is turned on within the switching operation period, whereby noise and surge voltage increase, as a first problem. In addition, in the driving method in which the delayed control signal input terminal is turned on within the switching operation period, a general problem in active gate driving, i.e., robustness against various conditions such as load current, a temperature, and gate threshold voltage variations, arises as a second problem.

The present disclosure has been made to solve the above problems, and an object of the present disclosure is to provide a semiconductor driving device and a power conversion device that have high robustness and enable improvement in trade-off between switching loss, and noise and surge voltage occurring in switching operation of a multi-gate semiconductor switching element.

### Means to Solve the Problem

A semiconductor driving device according to the present disclosure is a semiconductor driving device for driving a multi-gate semiconductor switching element having a plurality of gate terminals, the semiconductor driving device including: a timing generation unit which generates gate ON reference signals respectively for the plurality of gate terminals on the basis of an ON/OFF reference signal from outside; a gate reference waveform generation unit which generates a first gate reference waveform corresponding to at least one first gate terminal and a second gate reference waveform corresponding to at least one second gate terminal, among the plurality of gate terminals, on the basis of the gate ON reference signals, and controls one or both of the first gate reference waveform and the second gate reference waveform in one or both of shifting from a non-conductive state to a conductive state of the multi-gate semiconductor switching element and shifting from a conductive state to a non-conductive state of the multi-gate semiconductor switching element; and a signal amplification unit which receives, as an input waveform, one or both of the first gate reference waveform and the second gate reference waveform, and amplifies the input waveform so that an output waveform follows the input waveform.

A power conversion device according to the present disclosure includes: a device which has a multi-gate semiconductor switching element as a semiconductor switching element and which is one of an inverter device which converts DC power to AC power, a boost converter device which steps up voltage of DC power, a buck converter device which steps down voltage of DC power, an AC-DC converter device which converts AC power to DC power, a boost inverter device which includes the boost converter device and the inverter device, and a buck inverter device which includes the buck converter device and the inverter device; and the semiconductor driving device which drives the multi-gate semiconductor switching element, described above.

### Effect of the Invention

The semiconductor driving device and the power conversion device using the semiconductor driving device according to the present disclosure are configured to perform gate driving of a double-gate semiconductor switching element through such feedforward control as to follow a gate reference waveform, whereby it becomes possible to freely restrict the change rate of gate terminal voltage, thus providing an effect of suppressing noise and surge voltage even in a case of performing driving with a short time difference between gate terminals of a double-gate semiconductor switching element.

### BRIEF DESCRIPTION OF THE DRAWINGS

FIG. 1 is a block diagram showing the configuration of a semiconductor driving device according to embodiment 1;

FIG. 2A is a circuit diagram showing an example of a specific configuration of a signal amplification unit in the semiconductor driving device according to embodiment 1;

FIG. 2B is a circuit diagram showing an example of a specific configuration of a signal amplification unit in the semiconductor driving device according to embodiment 1;

FIG. 2C is a circuit diagram showing an example of a specific configuration of a signal amplification unit in the semiconductor driving device according to embodiment 1;

FIG. 2D is a circuit diagram showing an example of a specific configuration of a signal amplification unit in the semiconductor driving device according to embodiment 1;

FIG. 3A shows an example of a specific configuration of a gate reference generation unit in the semiconductor driving device according to embodiment 1;

FIG. 3B shows an example of a specific configuration of a gate reference generation unit in the semiconductor driving device according to embodiment 1;

FIG. 3C shows an example of a specific configuration of a gate reference generation unit in the semiconductor driving device according to embodiment 1;

FIG. 3D shows an example of a specific configuration of a gate reference generation unit in the semiconductor driving device according to embodiment 1;

FIG. 3E shows an example of a specific configuration of a gate reference generation unit in the semiconductor driving device according to embodiment 1;

FIG. 3F shows an example of a specific configuration of a gate reference generation unit in the semiconductor driving device according to embodiment 1;

FIG. 4A shows an example of a specific configuration of a gate reference generation unit in the semiconductor driving device according to embodiment 1;

FIG. 4B shows an example of a specific configuration of a gate reference generation unit in the semiconductor driving device according to embodiment 1;

FIG. 5 shows an example of a timing chart of each signal in the semiconductor driving device according to embodiment 1;

FIG. 6 shows an example of a timing chart of each signal in a semiconductor driving device according to modification 1 of embodiment 1;

FIG. 7 shows an example of a timing chart of each signal in a semiconductor driving device according to modification 2 of embodiment 1;

FIG. 8 is a block diagram showing the configuration of a semiconductor driving device according to embodiment 2;

FIG. 9 is a block diagram showing the configuration of a power conversion device according to embodiment 3;

FIG. 10 is a block diagram showing the configuration of a power conversion device according to embodiment 4;

FIG. 11 is a block diagram showing the configuration of a power conversion device according to embodiment 5;

FIG. 12 is a circuit diagram showing a configuration example of a gate driving unit in a semiconductor driving device according to Comparative example;

FIG. 13 is a schematic waveform diagram illustrating a problem in turn-on driving in a case where a short time difference is given between two gate terminals in the semiconductor driving device according to Comparative example;

FIG. 14 shows an example of hardware of the semiconductor driving device according to embodiment 1 and the power conversion device according to embodiments 2 to 5.

### DESCRIPTION OF EMBODIMENTS

### Embodiment 1

Hereinafter, embodiment 1 will be described with reference to the drawings. In the following description, the same or corresponding components are denoted by the same reference characters. Here, isolator components for isolating an ON/OFF reference signal inputted from a host side to a semiconductor driving device 100, e.g., a photocoupler, an optical fiber module, a pulse transformer, a clamp diode for gate voltage protection, and a short-circuit protection circuit, are not shown.

### Configuration of Semiconductor Driving Device According to Embodiment 1

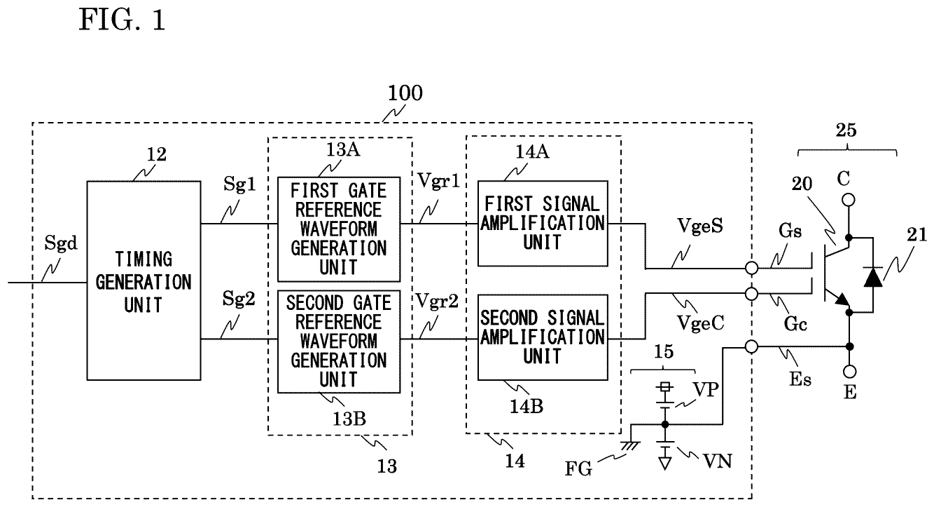

FIG. 1 is a block diagram showing the configuration of the semiconductor driving device 100 according to embodiment 1. In FIG. 1, as an example of the semiconductor driving device 100, a configuration for driving an IGBT module 25 having a combination of a double-gate IGBT 20 and a diode 21 is shown. For driving voltages applied to gate terminals of the double-gate IGBT 20, i.e., gate voltages Vge, an emitter potential FG is used as a reference, with positive-side voltage denoted by VP and negative-side voltage denoted by VN.

The semiconductor driving device 100 according to embodiment 1 includes a timing generation unit 12, a gate reference waveform generation unit 13, a signal amplification unit 14, and a driving voltage generation unit 15. The gate reference waveform generation unit 13 includes a first gate reference waveform generation unit 13A and a second gate reference waveform generation unit 13B, The signal amplification unit 14 includes a first signal amplification unit 14A and a second signal amplification unit 14B.

On the basis of an ON/OFF reference signal Sgd inputted from the outside of the semiconductor driving device 100, the timing generation unit 12 generates a driving timing for a first gate terminal Gs which is a switching gate of the double-gate IGBT 20 and a driving timing for a second gate terminal Gc which is a control gate of the double-gate IGBT 20, and outputs the driving timings as a first gate ON reference signal Sg1 and a second gate ON reference signal Sg2. The first gate ON reference signal Sg1 is a signal corresponding to the first gate terminal Gs of the double-gate IGBT 20, and the second gate ON reference signal Sg2 is a signal corresponding to the second gate terminal Gc of the double-gate IGBT 20.

In the gate reference waveform generation unit 13,

the first gate reference waveform generation unit 13A generates a first gate reference waveform Vgr1 on the basis of the first gate ON reference signal Sg1 outputted from the timing generation unit 12. In addition, in the gate reference waveform generation unit 13, the second gate reference waveform generation unit 13B generates a second gate reference waveform Vgr2 on the basis of the second gate ON reference signal Sg2 outputted from the timing generation unit 12.

The signal amplification unit 14 amplifies the first gate reference waveform Vgr1 and the second gate reference waveform Vgr2 outputted from the gate reference waveform generation unit 13, and outputs the amplified voltages to the double-gate IGBT 20 provided outside the semiconductor driving device 100. That is, the first signal amplification unit 14A amplifies the inputted first gate reference waveform Vgr1 and outputs first gate voltage VgeS, and the second signal amplification unit 14B amplifies the inputted second gate reference waveform Vgr2 and outputs second gate voltage VgeC, to the double-gate IGBT 20 provided outside the semiconductor driving device 100. The first gate voltage VgeS is applied to the first gate terminal Gs of the double-gate IGBT 20, and the second gate voltage VgeC is applied to the second gate terminal Gc of the double-gate IGBT 20.

The semiconductor driving device 100 according to embodiment 1 has a feature that the gate reference waveform generation unit 13 generates gate reference waveforms as desired waveforms in advance, and the signal amplification unit 14 amplifies the gate reference waveforms, thereby performing gate driving of the double-gate semiconductor switching element through feedforward control so as to follow the gate reference waveforms in the double-gate IGBT 20.

### Configurations of Components of Semiconductor Driving Device According to Embodiment 1

Specific configurations of the components composing the semiconductor driving device 100 according to embodiment 1, i.e., the timing generation unit 12, the gate reference waveform generation unit 13, and the signal amplification unit 14, will be described below. These components are not limited to the shown configurations, and may be formed from a combination of the shown configurations or by adding a component, or may be formed by another configuration for implementing the same function.

### Specific Configuration Examples of Signal Amplification Unit 14

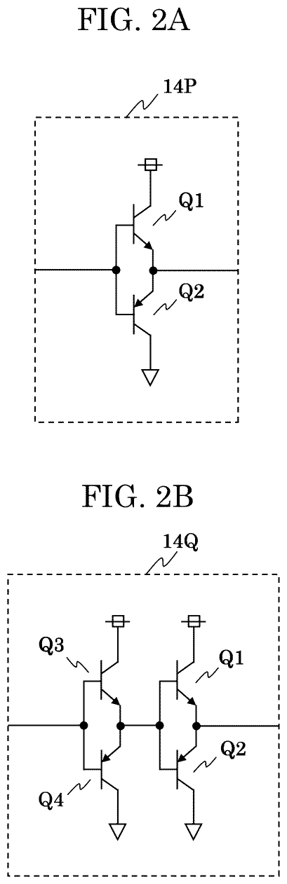

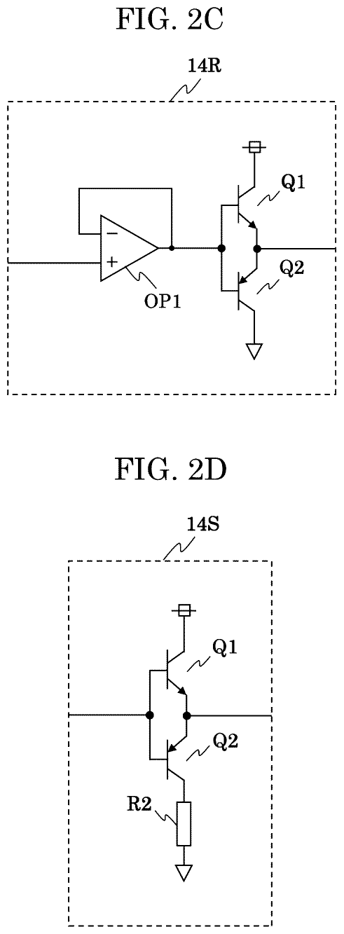

FIG. 2A, FIG. 2B, FIG. 2C, and FIG. 2D are circuit diagrams showing examples of specific configurations of the first signal amplification unit 14A and the second signal amplification unit 14B in the signal amplification unit 14 of the semiconductor driving device 100 according to embodiment 1. In FIG. 2A, FIG. 2B, FIG. 2C, and FIG. 2D, a base resistor is not shown, for simplification of the configurations. However, a base resistor may be added as necessary. The signal amplification unit 14 receives one or both of the first gate reference waveform and the second gate reference waveform as input waveforms, and amplifies the input waveforms so that output waveforms follow the input waveforms.

The above operation of “amplifying input waveforms so that output waveforms follow the input waveforms” will be described below.

The semiconductor driving device 100 is desired to give gate reference waveforms which are input signals to the gate terminals, but in a case where the capacity of a load connected to the semiconductor driving device 100 is large, the output voltage waveforms are changed from the waveforms of the input signals. For example, in a gate reference waveform, a mirror period (terrace-shaped stagnation period) appears due to dynamic change in the load capacity, and the signal amplification unit 14 operates so as to cause large current to flow in the mirror period so that an output waveform coincides with, i.e., follows the gate reference waveform. On the other hand, if a load impedance increases, the signal amplification unit 14 operates so as to reduce current so that an output waveform coincides with, i.e., follows the gate reference waveform. For example, in a case where the signal amplification unit 14 has the configuration shown in FIG. 2A, current is automatically adjusted so that output voltage on the right side in FIG. 2A coincides with base voltage on the left side in FIG. 2A. It can be said that such adjustment amplifies the input waveform so that an output waveform follows the input waveform. Therefore, an amplification factor for voltage of the signal amplification unit 14 may be 1.

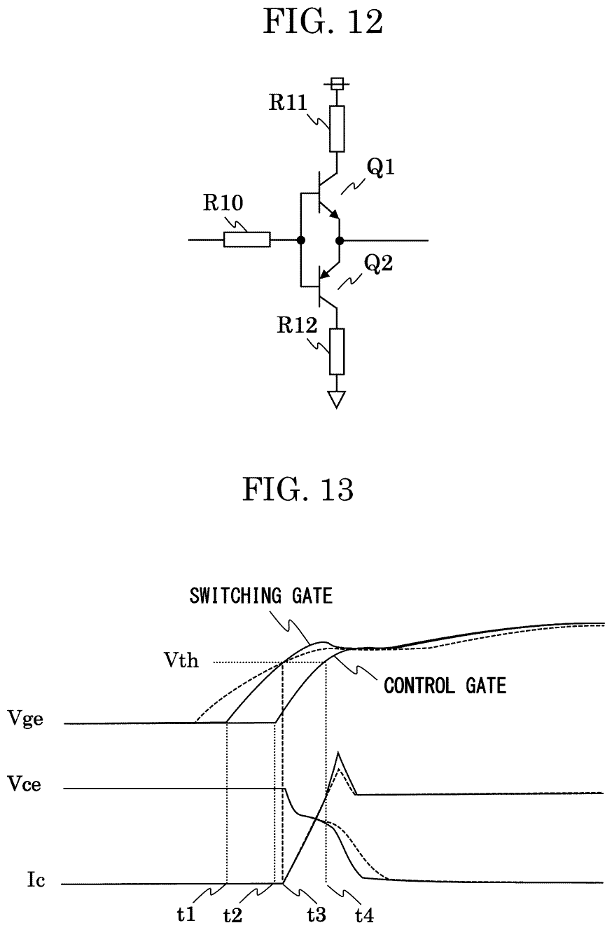

FIG. 2A is a circuit diagram showing the configuration of a signal amplification unit 14P. The signal amplification unit 14P is configured as a complementary emitter follower circuit composed of an NPN transistor Q1 and a PNP transistor Q2. In a constant voltage driving circuit in Comparative example shown in FIG. 12 described later, gate current is limited by a gate resistor. In the configuration of the signal amplification unit 14P of the semiconductor driving device 100 according to embodiment 1, gate current is automatically adjusted so that an output waveform follows an inputted voltage waveform.

In the signal amplification unit 14P, output voltage is reduced by threshold voltage of the NPN transistor Q1 and the PNP transistor Q2, and the maximum value of gate current is limited by current driving performance of the NPN transistor Q1 and the PNP transistor Q2. Therefore, a waveform difference might arise between the inputted voltage waveform and the output waveform. As a method for preventing malfunction in which the output waveform is distorted due to the threshold voltage of the NPN transistor Q1 and the PNP transistor Q2, a known method in which a diode for compensating the threshold voltage is added to the base terminal may be adopted.

FIG. 2B is a circuit diagram showing the configuration of a signal amplification unit 140. The signal amplification unit 140 is configured as a complementary emitter follower circuit composed of an NPN transistor Q1, a PNP transistor Q2, an NPN transistor Q3, and a PNP transistor Q4. The above signal amplification unit 14P is configured as a complementary emitter follower circuit with one stage, whereas the signal amplification unit 140 is configured as a complementary emitter follower circuit with two stages. With the configuration of the signal amplification unit 140, an effect of further increasing the current driving force of the signal amplification unit 14 is provided.

FIG. 2C is a circuit diagram showing the configuration of a signal amplification unit 14R. The signal amplification unit 14R is configured such that a voltage follower circuit having an operational amplifier OP1 (operational amplifier) is added at a stage preceding the complementary emitter follower circuit composed of the NPN transistor Q1 and the PNP transistor Q2. The configuration of the signal amplification unit 14R provides an effect of preventing the inputted voltage waveform from changing by current being consumed as base currents of the NPN transistor Q1 and the PNP transistor Q2 of the complementary emitter follower circuit at the subsequent stage.

FIG. 2D is a circuit diagram showing the configuration of a signal amplification unit 14S. The signal amplification unit 14S is configured such that a gate resistor R2 is added on an OFF side of the complementary emitter follower circuit composed of the NPN transistor Q1 and the PNP transistor Q2. The configuration of the signal amplification unit 14S makes it possible to simplify the configuration of the gate reference waveform generation unit 13 by performing conventional constant voltage driving at the time of turn-off operation while applying the signal amplification unit 14S at the time of turn-on operation in which the effect provided by the semiconductor driving device 100 according to embodiment 1 is high.

### Specific Configuration Example I of Gate Reference Waveform Generation Unit 13

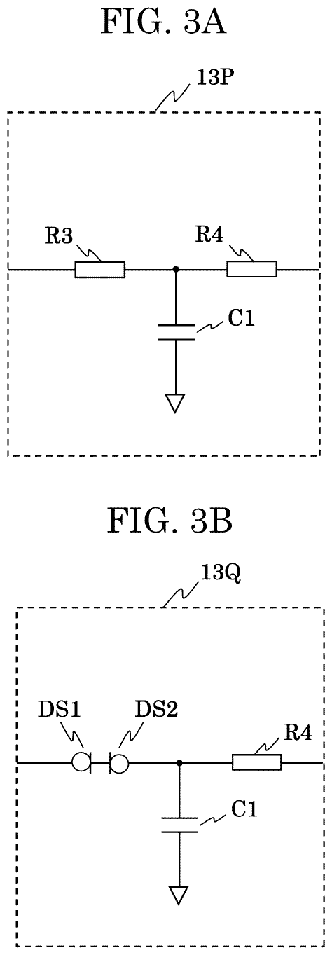

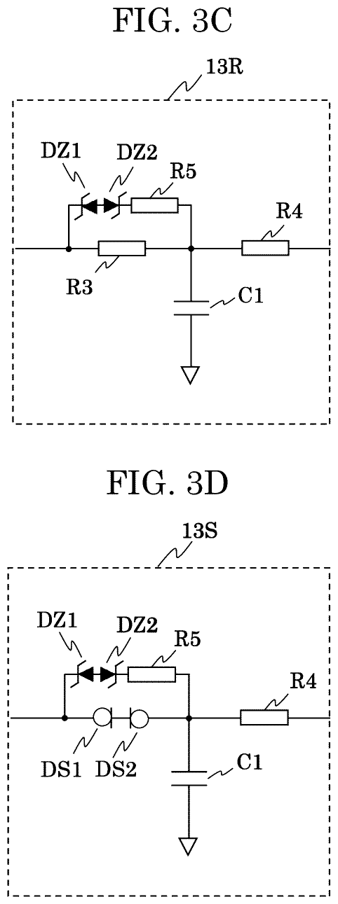

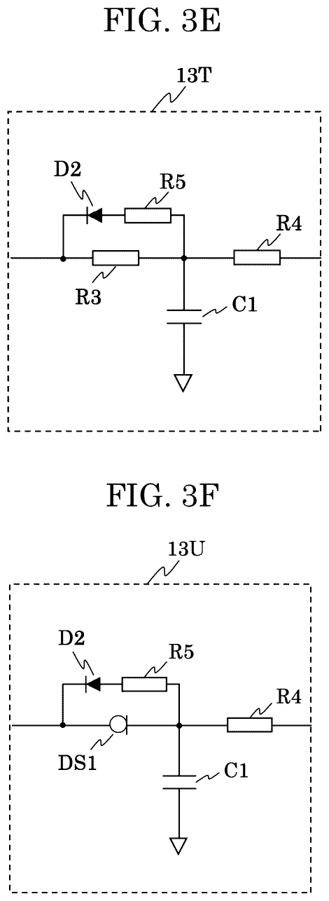

FIG. 3A, FIG. 3B, FIG. 3C, FIG. 3D, FIG. 3E, and FIG. 3F are circuit diagrams showing examples of specific configurations of the first gate reference waveform generation unit 13A and the second gate reference waveform generation unit 13B in the gate reference waveform generation unit 13 of the semiconductor driving device 100 according to embodiment 1, The gate reference waveform generation unit 13 is configured to control waveforms by controlling one or both of a differential value of the first gate reference waveform and a differential value of the second gate reference waveform.

FIG. 3A is a circuit diagram showing a gate reference waveform generation unit 13P. The gate reference waveform generation unit 13P generates, as a gate reference waveform, a CR charge/discharge waveform based on a resistor R3 and a capacitor C1, i.e., a waveform in which a second-order differential value of voltage is less than zero (d²V/dt²<0). The resistor R4 serves as a base resistor for limiting base current of the signal amplification unit 14 at the subsequent stage. It suffices that at least one of gate reference waveforms partially includes a charge voltage shape or a discharge voltage shape formed by a capacitor and a resistor.

FIG. 3B is a circuit diagram showing a gate reference waveform generation unit 130. The gate reference waveform generation unit 130 is configured such that constant current diodes DS1 and DS2 are used instead of the resistor R3 of the gate reference waveform generation unit 13P shown in FIG. 3A. The gate reference waveform generation unit 13Q generates a ramp-shaped waveform having a constant slope, i.e., a waveform in which a second-order differential value of voltage is zero (d²V/dt²=0).

FIG. 3C is a circuit diagram showing a gate reference waveform generation unit 13R, The gate reference waveform generation unit 13R is configured such that zener diodes DZ1 and DZ2 and a resistor R5 are provided in parallel to the resistor R3 of the gate reference waveform generation unit 13P shown in FIG. 3A. The gate reference waveform generation unit 13R functions to increase the magnitude of the slope of a gate reference waveform by increasing charge current and discharge current of the capacitor C1 immediately after the start of turning on and immediately after the start of turning off.

FIG. 3D is a circuit diagram showing a gate reference waveform generation unit 13S. The gate reference waveform generation unit 13S is configured such that the same change as the change to the gate reference waveform generation unit 13R shown in FIG. 3C with respect to the gate reference waveform generation unit 13P shown in FIG. 3A is applied to the gate reference waveform generation unit 13Q shown in FIG. 3B. That is, zener diodes DZ1 and DZ2 and a resistor R5 are provided in parallel to the constant current diodes DS1 and DS2 of the gate reference waveform generation unit 13Q shown in FIG. 3B.

FIG. 3E is a circuit diagram showing a gate reference waveform generation unit 13T. In the gate reference waveform generation unit 13T, a diode D2 and a resistor R5 are added in parallel to the resistor R3 of the gate reference waveform generation unit 13P shown in FIG. 3A, whereby a gate reference waveform at the time of turn-off operation is made into a rectangular waveform, and turn-off operation is performed by constant voltage driving in combination with the signal amplification unit 14S shown in FIG. 2D.

FIG. 3F is a circuit diagram showing a gate reference waveform generation unit 13U. The gate reference waveform generation unit 13U is configured such that the same change as the change to the gate reference waveform generation unit 13T shown in FIG. 3E with respect to the gate reference waveform generation unit 13P shown in FIG. 3A is applied to the gate reference waveform generation unit 130 shown in FIG. 3B. That is, a diode D2 and a resistor R5 are added in parallel to the resistor R3 of the gate reference waveform generation unit 13P shown in FIG. 3B.

### Specific Configuration Example II of Gate Reference Waveform Generation Unit 13

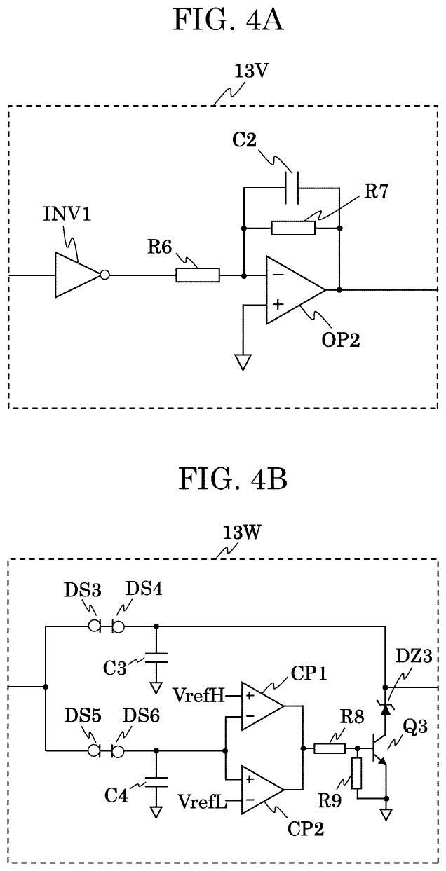

The configuration examples of the gate reference waveform generation unit 13 shown in FIG. 3A to FIG. 3F described above are configurations using a resistor, a capacitor, and various diodes. On the other hand, examples of the gate reference waveform generation unit 13 shown in FIG. 4A and FIG. 4B described below are configuration examples using an operational amplifier, a comparator, and the like.

FIG. 4A is a circuit diagram showing a gate reference waveform generation unit 13V. The gate reference waveform generation unit 13V is configured such that a logic inverting circuit INVI and an integration circuit formed by an operational amplifier OP2, a resistor R6, a resistor R7, and a capacitor C2 are combined. The gate reference waveform generation unit 13V generates a ramp-shaped waveform having a constant slope, i.e., a waveform in which a second-order differential value of voltage is zero (d²V/dt² =0), as with the waveform of the gate reference waveform generation unit 13P shown in FIG. 3B.

FIG. 4B is a circuit diagram showing a gate reference waveform generation unit 13W. The gate reference waveform generation unit 13W includes: a window comparator which is composed of comparators CP1 and CP2 and performs determination as to a reference range not less than VrefL but less than VrefH; a voltage limiting circuit composed of a zener diode DZ3 and an NPN transistor Q3; two identical ramp-shaped waveform generation circuits composed of constant current diodes DS3 and DS4 and a capacitor C3, and constant current diodes DS5 and DS6 and a capacitor C4, respectively; a resistor R8; and a resistor R9. Regarding a waveform generated by the gate reference waveform generation unit 13W, when a ramp-shaped waveform as a reference is within a reference range not less than VrefL but less than VrefH, a terrace-shaped waveform determined by zener voltage of DZ3, i.e., a waveform in which a first-order differential value of voltage is zero (dV/dt=0), can be provided to a ramp-shaped waveform to be outputted.

### Operation of Semiconductor Driving Device According to Embodiment 1

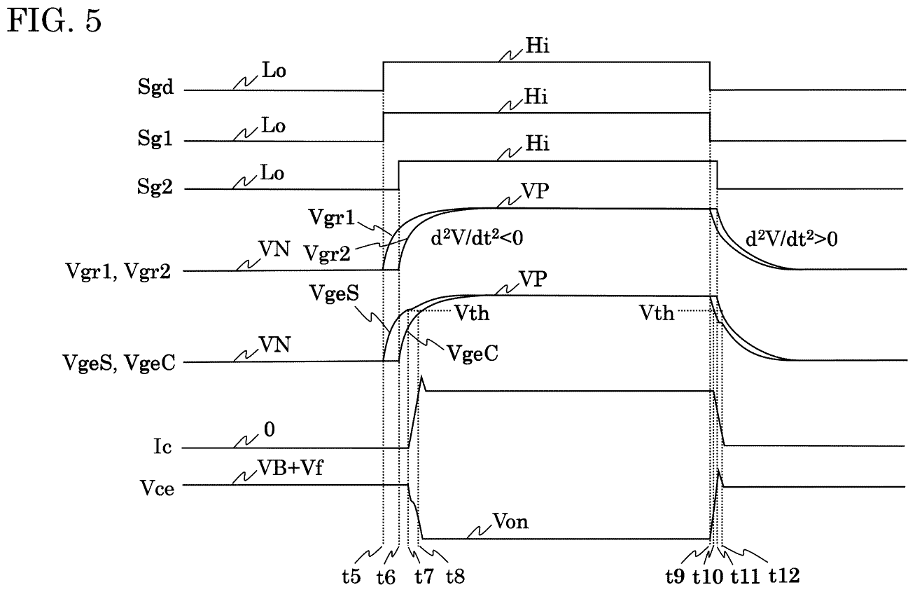

FIG. 5 shows an example of a timing chart of each signal representing operation of the semiconductor driving device 100 according to embodiment 1. As a specific configuration of the gate reference waveform generation unit 13 of the semiconductor driving device 100 according to embodiment 1, the gate reference waveform generation unit 13P shown in FIG. 3A is applied. The gate reference waveform generation unit 13P generates, as a gate reference waveform, a CR charge/discharge waveform based on the resistor R3 and the capacitor C1, i.e., a waveform in which a second-order differential value of voltage is less than zero (d₂V/dt²<0). It suffices that at least one of gate reference waveforms partially includes a charge voltage shape or a discharge voltage shape formed by a capacitor and a resistor,

The waveforms shown in FIG. 5 are, from the top, the ON/OFF reference signal Sgd, the first gate ON reference signal Sg1, the second gate ON reference signal Sg2, the first gate reference waveform Vgr1 and the second gate reference waveform Vgr2, the first gate voltage VgeS, the second gate voltage VgeC, collector current Ic, and collector voltage Vce.

Hereinafter, operation of the semiconductor driving device 100 according to embodiment 1 will be described with reference to FIG. 5.

### Turn-On Operation of Semiconductor Driving Device According to Embodiment 1

First, sequential operations of each signal when the ON/OFF reference signal Sgd is turned from off to on, i.e., in turn-on operation, will be described. At time t5, the ON/OFF reference signal Sgd from outside is turned from off to on. That is, the ON/OFF reference signal Sgd is turned from Lo state to Hi state. At time t5, the timing generation unit 12 outputs the first gate ON reference signal Sg1 on the basis of ON operation of the ON/OFF reference signal Sgd. That is, the first gate ON reference signal Sg1 is turned from Lo state to Hi state.

At time t6, the timing generation unit 12 outputs the second gate ON reference signal Sg2 on the basis of ON operation of the ON/OFF reference signal Sgd, The second gate ON reference signal Sg2 is outputted with a delay by a predetermined period, i.e., a time difference t6−t5, from the first gate ON reference signal Sg1.

At time t5, the first gate reference waveform

generation unit 13A generates the first gate reference waveform Vgr1 on the basis of ON operation of the first gate ON reference signal Sg1. The first gate reference waveform Vgr1 rises from time t5, and since the circuit configuration of the gate reference waveform generation unit 13P is applied as the first gate reference waveform generation unit 13A, the first gate reference waveform Vgr1 becomes such a waveform that the increase rate of voltage is limited, i.e., a waveform in which a second-order differential value of voltage is less than zero (d²V/dt²<0).

At time t6, the second gate reference waveform generation unit 13B generates the second gate reference waveform Vgr2 on the basis of ON operation of the second gate ON reference signal Sg2. The second gate reference waveform Vgr2 rises from time t6, and since the circuit configuration of the gate reference waveform generation unit 13P is applied as the second gate reference waveform generation unit 13B, the second gate reference waveform Vgr2 becomes such a waveform that the increase rate of voltage is limited, i.e., a waveform in which a second-order differential value of voltage is less than zero (d²V/dt²<0). The second gate reference waveform Vgr2 is outputted with a delay by a predetermined period, i.e., a time difference t6−t5, from the first gate reference waveform Vgr1.

At time t5, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the increase rate of voltage is limited, i.e., a waveform in which a second-order differential value of voltage is less than zero (d²V/dt²<0).

At time t6, the second signal amplification unit 14B amplifies the inputted second gate reference waveform Vgr2 and outputs the second gate voltage VgeC. The second gate voltage VgeC reflects the second gate reference waveform Vgr2 and thus becomes such a waveform that the increase rate of voltage is limited, i.e., a waveform in which a second-order differential value of voltage is less than zero (d²V/dt²<0). The second gate voltage VgeC is outputted with a delay by a predetermined period, i.e., a time difference t6−t5, from the first gate voltage Vges.

The first gate voltage VgeS and the second gate voltage VgeC are respectively outputted to the first gate terminal Gs and the second gate terminal Gc of the double-gate IGBT 20 provided outside the semiconductor driving device 100.

At time t7 when the first gate voltage VgeS becomes equal to or greater than the threshold voltage Vth, the collector current Ic of the double-gate IGBT 20 rises from a zero state that has continued before time t7, and becomes a constant value at time t8 when the second gate voltage VgeC becomes equal to or greater than the threshold voltage Vth.

At time t7 when the first gate voltage VgeS becomes equal to or greater than the threshold voltage Vth, the collector voltage Vce of the double-gate IGBT 20 decreases from a state of VB+Vf that has continued before time t7, and becomes ON voltage Von which is a constant value, at time t8 when the second gate voltage VgeC becomes equal to or greater than the threshold voltage Vth.

The sequential operations of each signal when the ON/OFF reference signal Sgd is turned from off to on, i.e., in turn-on operation, are as described above.

### Turn-Off Operation of Semiconductor Driving Device According to Embodiment 1

Next, sequential operations of each signal when the ON/OFF reference signal Sgd is turned from on to off, i.e., in turn-off operation, will be described.

At time t9, the ON/OFF reference signal Sgd from outside is turned from on to off. That is, the ON/OFF reference signal Sgd is turned from Hi state to Lo state. At time t9, the timing generation unit 12 turns off the first gate ON reference signal Sg1 on the basis of OFF operation of the ON/OFF reference signal Sgd. That is, the first gate ON reference signal Sg1 is turned from Hi state to Lo state.

At time t10, the timing generation unit 12 turns off the second gate ON reference signal Sg2 on the basis of OFF operation of the ON/OFF reference signal Sgd. The OFF operation of the second gate ON reference signal Sg2 occurs with a delay by a predetermined period, i.e., a time difference t10−t9, from the OFF operation of the first gate ON reference signal Sg1.

At time t9, the first gate reference waveform generation unit 13A turns off the first gate reference waveform Vgr1 on the basis of OFF operation of the first gate ON reference signal Sg1. The first gate reference waveform Vgr1 falls from time t9, and since the circuit configuration of the gate reference waveform generation unit 13P is applied as the first gate reference waveform generation unit 13A, the first gate reference waveform Vgr1 becomes such a waveform that the decrease rate of voltage is limited, i.e., a waveform in which a second-order differential value of voltage is greater than zero (d²V/dt²>0).

At time t10, the second gate reference waveform generation unit 13B turns off the second gate reference waveform Vgr2 on the basis of OFF operation of the second gate ON reference signal Sg2. The second gate reference waveform Vgr2 falls from time t10, and since the circuit configuration of the gate reference waveform generation unit 13P is applied as the second gate reference waveform generation unit 13B, the second gate reference waveform Vgr2 becomes such a waveform that the decrease rate of voltage is limited, i.e., a waveform in which a second-order differential value of voltage is greater than zero (d²V/dt²>0). The OFF operation of the second gate reference waveform Vgr2 occurs with a delay by a predetermined period, i.e., a time difference t10−t9, from the OFF operation of the first gate reference waveform Vgr1.

At time t9, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the decrease rate of voltage is limited, i.e., a waveform in which a second-order differential value of voltage is greater than zero (d²V/dt²>0).

At time t10, the second signal amplification unit 14B amplifies the inputted second gate reference waveform Vgr2 and outputs the second gate voltage VgeC. The second gate voltage VgeC reflects the second gate reference waveform Vgr2 and thus becomes such a waveform that the decrease rate of voltage is limited, i.e., a waveform in which a second-order differential value of voltage is greater than zero (d²V/dt²>0). The OFF operation of the second gate voltage VgeC occurs with a delay by a predetermined period, i.e., a time difference t10−t9, from the OFF operation of the first gate voltage VgeS.

The first gate voltage Vges and the second gate voltage VgeC are respectively outputted to the first gate terminal Gs and the second gate terminal Gc of the double-gate IGBT 20 provided outside the semiconductor driving device 100.

At time t10 when OFF operation of the second gate ON reference signal Sg2 is started, the collector current Ic of the double-gate IGBT 20 falls from the constant state that has continued, and becomes zero at time t12 when the second gate voltage VgeC becomes less than the threshold voltage Vth.

At time t9 when OFF operation of the first gate ON reference signal Sg1 is started, the collector voltage Vce of the double-gate IGBT 20 increases from the state of ON voltage Von that has continued, and returns to the constant value VB+Vf at time t12 when the second gate voltage VgeC becomes less than the threshold voltage Vth.

The sequential operations of each signal when the ON/OFF reference signal Sgd is turned from on to off, i.e., in turn-off operation, are as described above.

In the semiconductor driving device 100 according to embodiment 1, as shown in FIG. 5, the first gate reference waveform Vgr1 and the second gate reference waveform Vgr2 in turn-on operation are controlled so that the increase rates thereof are limited, i.e., second-order differential values of voltages are less than zero (d²V/dt²<0), whereby it becomes possible to suppress increase in a collector current change rate dIc/dt which occurs when the second gate terminal Gc which is the control gate is turned on, and thus noise in switching operation can be suppressed.

In addition, in the semiconductor driving device 100 according to embodiment 1, as shown in FIG. 5, the first gate reference waveform Vgr1 and the second gate reference waveform Vgr2 in turn-off operation are controlled so that the decrease rates thereof are limited, i.e., second-order differential values of voltages are greater than zero (d²V/dt²>0), whereby it becomes possible to suppress decrease in the collector current change rate dIc/dt which occurs when the second gate terminal Gc which is the control gate is turned off. Thus, surge voltage can be suppressed. Further, by setting the same CR time constant for the first gate reference waveform Vgr1 and the second gate reference waveform Vgr2 which are two gate reference waveforms, an effect of increasing robustness described above is provided.

### Comparative Example

FIG. 12 shows an example of a constant voltage driving circuit that implements a constant voltage driving method applied in a semiconductor driving device according to Comparative example, and FIG. 13 shows schematic waveforms in a case where the double-gate IGBT 20 is driven with a time difference given between two gate voltage waveforms in the semiconductor driving device according to Comparative example. Hereinafter, a problem in the semiconductor driving device according to Comparative example will be described.

The configuration of the semiconductor driving device according to Comparative example is disclosed in, for example, Patent Document 1. In the semiconductor driving device according to Comparative example, in a case of obtaining the above active gate effect by setting the time difference to be short so that the timing of turning on/off one gate terminal of the double-gate IGBT 20 after turning on/off the other gate terminal is within a switching operation period, two problems shown below arise.

First, a first problem will be described. The constant voltage driving circuit shown in FIG. 12 has a configuration in which a rectangular-wave signal inputted from the left side in FIG. 12 undergoes current amplification by a buffer circuit composed of an NPN transistor Q1 and a PNP transistor Q2 via a base resistor R10. In the constant voltage driving method according to Comparative example, the gate current value is limited by the gate resistor R11 and the gate resistor R12.

FIG. 13 shows schematic waveforms in a case where the semiconductor driving device according to Comparative example is operated by the constant voltage driving method and the double-gate IGBT 20 is driven with a short time difference given between two gate voltage waveforms. In FIG. 13, driving waveforms for a single-gate IGBT in Comparative example are represented by broken lines, and driving waveforms for the double-gate IGBT 20 in Comparative example are represented by solid lines.

In the double-gate IGBT 20 driven by the semiconductor driving device according to Comparative example, a short time difference (t2−t1) is given between gate voltages to be applied to the switching gate Gs serving for switching and the control gate Gc for controlling the carrier injection amount. At time t3 when the switching gate Gs exceeds the threshold voltage Vth, the collector current Ic starts to flow, but since only some of cells connected to the switching gate Gs serve for the collector current Ic to flow in, it is necessary to apply greater gate voltage Vge under a greater voltage change rate dVge/dt, in order to obtain a collector current change rate dIc/dt equivalent to that in the single-gate IGBT.

After the collector current Ic has started to flow in, at time t4 when the control gate Gc of the double-gate IGBT 20 reaches the threshold voltage Vth, current flows in the entire double-gate IGBT 20, so that conduction performance increases and the effect of the collector voltage Vce becomes sharp, thus providing an effect of reducing switching loss. At the same time, with increase in conduction performance, the collector current change rate dIc/dt increases after time t4. However, it is known that when dIc/dt increases, the voltage change rate dV/dt between the cathode and the anode increases due to recovery operation of an opposite arm diode composing the inverter, leading to noise increase. In addition, for the same reason, it is known that surge voltage increases in turn-off operation. As described above, increase in noise and surge voltage when the control gate Gc delayed within a switching operation period is turned on is the first problem in the semiconductor driving device according to Comparative example.

In the driving method of turning on the control gate Gc delayed within a switching operation period in the semiconductor driving device according to Comparative example, a general problem in active gate driving, i.e., deterioration in robustness against various conditions such as load current, a temperature, and gate threshold voltage variations, arises as a second problem in the semiconductor driving device according to Comparative example. The second problem is due to the fact that a time difference between two gate voltages around a mirror voltage level is not constant with respect to change in the mirror voltage level which occurs depending on the above various conditions.

As a clear example of the second problem, there is a case where the gate resistor of the control gate Gc of the double-gate IGBT 20 is set to be smaller than the gate resistor of the switching gate Gs so as to shorten a switching period. In this case, voltage level dependence of a time difference between two gate voltages increases, so that a problem of robustness becomes remarkable.

### Effects of Embodiment 1

As described above, with the semiconductor driving device according to embodiment 1, it becomes possible to solve the above problems arising in Comparative example, so that it becomes possible to make improvement in trade-off between switching loss, and noise and surge voltage occurring in switching of a multi-gate semiconductor switching element, thus providing an effect of obtaining a semiconductor driving device that has high robustness.

### Modification 1 of Embodiment 1

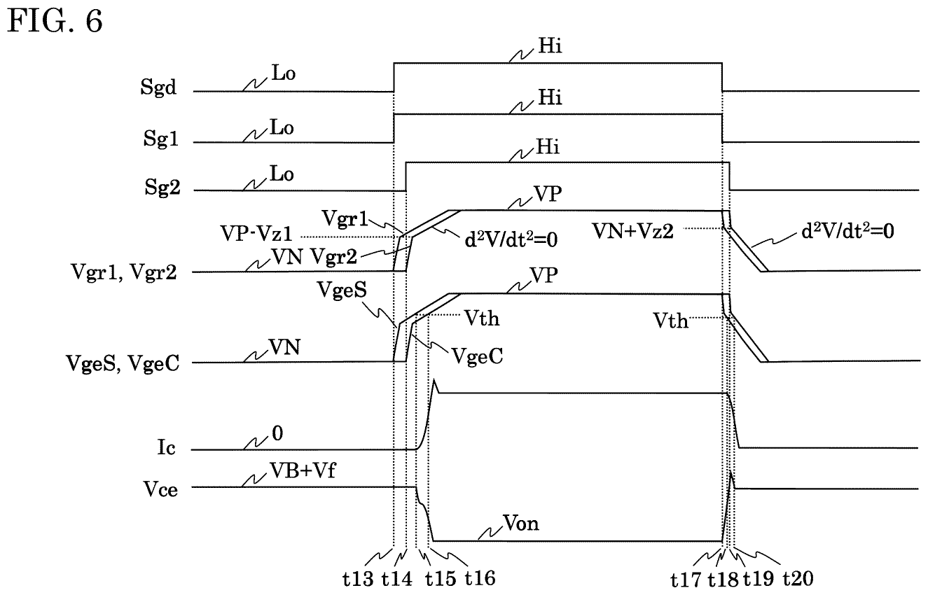

FIG. 6 shows an example of a timing chart of each signal in a semiconductor driving device according to modification 1 of embodiment 1. As a specific configuration of the gate reference waveform generation unit 13 of the semiconductor driving device according to modification 1 of embodiment 1, the gate reference waveform generation unit 13S shown in FIG. 3D is applied. The gate reference waveform generation unit 13S generates a gate reference waveform that partially has a ramp shape in which a second-order differential value of voltage is zero (d²V/dt² =0).

The waveforms shown in FIG. 6 are, from the top, the ON/OFF reference signal Sgd, the first gate ON reference signal Sg1, the second gate ON reference signal Sg2, the first gate reference waveform Vgr1 and the second gate reference waveform Vgr2, the first gate voltage VgeS, the second gate voltage VgeC, the collector current Ic, and the collector voltage Vce.

### Operation of Semiconductor Driving Device According to Modification 1 of Embodiment 1

Hereinafter, operation of the semiconductor driving device according to modification 1 of embodiment 1 will be described with reference to FIG. 6.

### Turn-On Operation of Semiconductor Driving Device According to Modification 1 of Embodiment 1

First, sequential operations of each signal when the ON/OFF reference signal Sgd is turned from off to on, i.e., in turn-on operation, will be described.

At time t13, the ON/OFF reference signal Sgd from outside is turned from off to on. That is, the ON/OFF reference signal Sgd is turned from Lo state to Hi state. At time t13, the timing generation unit 12 outputs the first gate ON reference signal Sg1 on the basis of ON operation of the ON/OFF reference signal Sgd. That is, the first gate ON reference signal Sg1 is turned from Lo state to Hi state.

At time t14, the timing generation unit 12 outputs the second gate ON reference signal Sg2 on the basis of ON operation of the ON/OFF reference signal Sgd. The second gate ON reference signal Sg2 is outputted with a delay by a predetermined period, i.e., a time difference t14—t13, from the first gate ON reference signal Sg1.

At time t13, the first gate reference waveform generation unit 13A generates the first gate reference waveform Vgr1 on the basis of ON operation of the first gate ON reference signal Sg1. The first gate reference waveform Vgr1 rises from time t13, and since the circuit configuration of the gate reference waveform generation unit 13S is applied as the first gate reference waveform generation unit 13A, the first gate reference waveform Vgr1 becomes such a waveform that partially has a ramp shape in which the increase rate of voltage is limited, i.e., a second-order differential value of voltage is zero (d²V/dt² =0).

At time t14, the second gate reference waveform

generation unit 13B generates the second gate reference waveform Vgr2 on the basis of ON operation of the second gate ON reference signal Sg2. The second gate reference waveform Vgr2 rises from time t14, and since the circuit configuration of the gate reference waveform generation unit 13S is applied as the second gate reference waveform generation unit 13B, the second gate reference waveform Vgr2 becomes such a waveform that partially has a ramp shape in which the increase rate of voltage is limited, i.e., a second-order differential value of voltage is zero (d²V/dt² =0). The second gate reference waveform Vgr2 is outputted with a delay by a predetermined period, i.e., a time difference t14−t13, from the first gate reference waveform Vgr1.

At time t13, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the first gate voltage VgeS partially has a ramp shape in which the increase rate of voltage is limited, i.e., a second-order differential value of voltage is zero (d²V/dt² =0).

At time t14, the second signal amplification unit 14B amplifies the inputted second gate reference waveform Vgr2 and outputs the second gate voltage VgeC. The second gate voltage VgeC reflects the second gate reference waveform Vgr2 and thus becomes such a waveform that the second gate voltage VgeC partially has a ramp shape in which the increase rate of voltage is limited, i.e., a second-order differential value of voltage is zero (d²V/dt² =0). The second gate voltage VgeC is outputted with a delay by a predetermined period, i.e., a time difference t14−t13, from the first gate voltage VgeS.

The first gate voltage Vges and the second gate voltage VgeC are respectively outputted to the first gate terminal Gs and the second gate terminal Gc of the double-gate IGBT 20 provided outside the semiconductor driving device 100.

At time t15 when the first gate voltage Vges becomes equal to or greater than the threshold voltage Vth, the collector current Ic of the double-gate IGBT 20 rises from a zero state that has continued before time t15, and becomes a constant value at time t16 when the second gate voltage VgeC becomes equal to or greater than the threshold voltage Vth.

At time t15 when the first gate voltage VgeS becomes equal to or greater than the threshold voltage Vth, the collector voltage Vce of the double-gate IGBT 20 decreases from a state of VB+Vf that has continued before time t15, and becomes ON voltage Von which is a constant value, at time t16 when the second gate voltage VgeC becomes equal to or greater than the threshold voltage Vth.

The sequential operations of each signal when the ON/OFF reference signal Sgd is turned from off to on, i.e., in turn-on operation, are as described above.

### Turn-Off Operation of Semiconductor Driving Device According to Modification 1 of Embodiment 1

Next, sequential operations of each signal when the ON/OFF reference signal Sgd is turned from on to off, i.e., in turn-off operation, will be described.

At time t17, the ON/OFF reference signal Sgd from

outside is turned from on to off. That is, the ON/OFF reference signal Sgd is turned from Hi state to Lo state. At time t17, the timing generation unit 12 turns off the first gate ON reference signal Sg1 on the basis of ON operation of the ON/OFF reference signal Sgd. That is, the first gate ON reference signal Sg1 is turned from Hi state to Lo state.

At time t18, the timing generation unit 12 turns off the second gate ON reference signal Sg2 on the basis of OFF operation of the ON/OFF reference signal Sgd. The OFF operation of the second gate ON reference signal Sg2 occurs with a delay by a predetermined period, i.e., a time difference t18−t17, from the OFF operation of the first gate ON reference signal Sg1.

At time t17, the first gate reference waveform generation unit 13A turns off the first gate reference waveform Vgr1 on the basis of OFF operation of the first gate ON reference signal Sg1. The first gate reference waveform Vgr1 falls from time t17, and since the circuit configuration of the gate reference waveform generation unit 13S is applied as the first gate reference waveform generation unit 13A, the first gate reference waveform Vgr1 becomes such a waveform that partially has a ramp shape in which the decrease rate of voltage is limited, i.e., a second-order differential value of voltage is zero (d²V/dt² =0).

At time t18, the second gate reference waveform generation unit 13B turns off the second gate reference waveform Vgr2 on the basis of OFF operation of the second gate ON reference signal Sg2. The second gate reference waveform Vgr2 falls from time t18, and since the circuit configuration of the gate reference waveform generation unit 13S is applied as the second gate reference waveform generation unit 13B, the second gate reference waveform Vgr2 becomes such a waveform that partially has a ramp shape in which the decrease rate of voltage is limited, i.e., a second-order differential value of voltage is zero (d²V/dt² =0). The OFF operation of the second gate reference waveform Vgr2 occurs with a delay by a predetermined period, i.e., a time difference t18−t17, from the OFF operation of the first gate reference waveform Vgr1.

At time t17, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the first gate voltage Vges partially has a ramp shape in which the decrease rate of voltage is limited, i.e., a second-order differential value of voltage is zero (d²V/dt² =0).

At time t18, the second signal amplification unit 14B amplifies the inputted second gate reference waveform Vgr2 and outputs the second gate voltage VgeC. The second gate voltage VgeC reflects the second gate reference waveform Vgr2 and thus becomes such a waveform that the second gate voltage VgeC partially has a ramp shape in which the decrease rate of voltage is limited, i.e., a second-order differential value of voltage is zero (d²V/dt² =0). The OFF operation of the second gate voltage VgeC occurs with a delay by a predetermined period, i.e., a time difference t18−t17, from the OFF operation of the first gate voltage VgeS.

The first gate voltage VgeS and the second gate voltage VgeC are respectively outputted to the first gate terminal Gs and the second gate terminal Gc of the double-gate IGBT 20 provided outside the semiconductor driving device according to modification 1 of embodiment 1.

At time t19 when the first gate voltage VgeS becomes less than the threshold voltage Vth, the collector current Ic of the double-gate IGBT 20 falls from the constant state that has continued, and becomes zero at time t20 when the second gate voltage VgeC becomes less than the threshold voltage Vth.

At time t19 when the first gate voltage Vges becomes less than the threshold voltage Vth, the collector voltage Vce of the double-gate IGBT 20 increases from the state of ON voltage Von that has continued, and returns to the constant value VB+Vf at time t20 when the second gate voltage VgeC becomes less than the threshold voltage Vth.

The sequential operations of each signal when the ON/OFF reference signal Sgd is turned from on to off, i.e., in turn-off operation, are as described above.

### Effects of Modification 1 of Embodiment 1

As described above, in the semiconductor driving device according to modification 1 of embodiment 1, control is performed so that the increase rate of the gate reference waveform in turn-on operation is limited, i.e., a second-order differential value of voltage is zero (d²V/dt² =0), whereby increase in the collector current change rate dIc/dt which occurs when the control gate Go is turned on is suppressed, and thus noise in switching operation can be suppressed. In the semiconductor driving device according to modification 1 of embodiment 1, in particular, since the second-order differential value of voltage is set to zero (d²V/dt² =0), control can be performed so that a time difference between two gate voltages does not depend on the voltage level, and thus robustness is improved. Also in turn-off operation, the same effects are provided and therefore the description thereof is omitted.

### Modification 2 of Embodiment 1

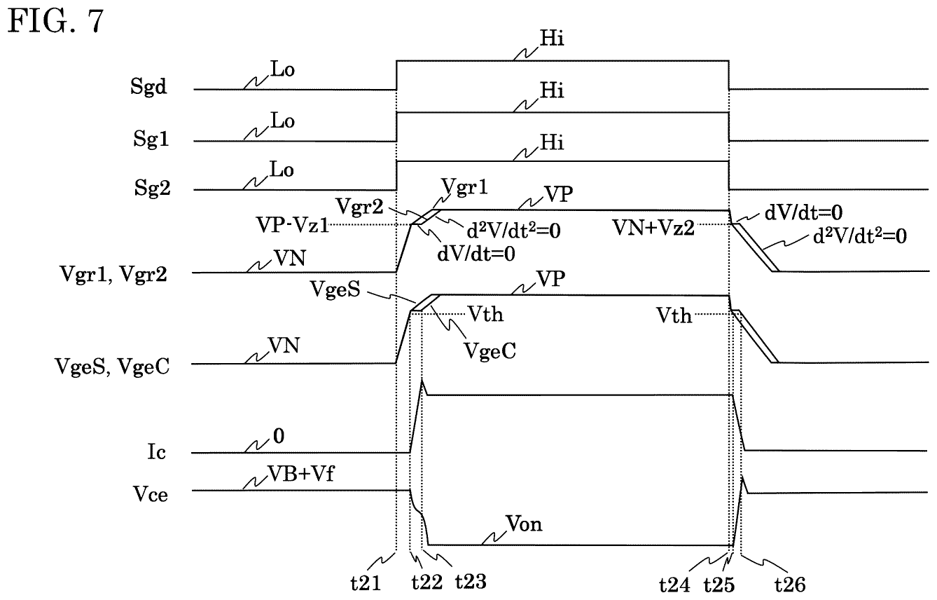

FIG. 7 shows an example of a timing chart of each signal in a semiconductor driving device according to modification 2 of embodiment 1, As a specific configuration of the gate reference waveform generation unit of the semiconductor driving device according to modification 2 of embodiment 1, the gate reference waveform generation unit 13W shown in FIG. 4B is applied. The gate reference waveform generation unit 13W generates such a waveform that a terrace shape in which a first-order differential value of voltage is zero (dV/dt=0) is provided at a part of a ramp shape.

That is, the semiconductor driving device according to modification 2 of embodiment 1 shown in FIG. 7 is characterized in that, as compared to modification 1 of embodiment 1 shown in FIG. 6, the timings of rising and falling of the first gate ON reference signal Sg1 and the second gate ON reference signal Sg2 which are two gate ON references are made to coincide with each other, and a terrace period is provided partway on, i.e., at a part of the ramp-shaped waveform.

The waveforms shown in FIG. 7 are, from the top, the ON/OFF reference signal Sgd, the first gate ON reference signal Sg1, the second gate ON reference signal Sg2, the first gate reference waveform Vgr1 and the second gate reference waveform Vgr2, the first gate voltage Vges, the second gate voltage VgeC, the collector current Ic, and the collector voltage Vce.

### Operation of Semiconductor Driving Device According to Modification 2 Of Embodiment 1

Hereinafter, operation of the semiconductor driving device according to modification 2 of embodiment 1 will be described with reference to FIG. 7.

### Turn-On Operation of Semiconductor Driving Device According to Modification 2 of Embodiment 1

First, sequential operations of each signal when the ON/OFF reference signal Sgd is turned from off to on, i.e., in turn-on operation, will be described. At time t21, the ON/OFF reference signal Sgd from outside is turned from off to on. That is, the ON/OFF reference signal Sgd is turned from Lo state to Hi state. At time t21, the timing generation unit 12 outputs the first gate ON reference signal Sg1 on the basis of ON operation of the ON/OFF reference signal Sgd. That is, the first gate ON reference signal Sg1 is turned from Lo state to Hi state.

At time t21, the timing generation unit 12 outputs the second gate ON reference signal Sg2 on the basis of ON operation of the ON/OFF reference signal Sgd. The second gate ON reference signal Sg2 is outputted at the same time as the first gate ON reference signal Sg1.

At time t21, the first gate reference waveform generation unit 13A generates the first gate reference waveform Vgr1 on the basis of ON operation of the first gate ON reference signal Sg1. The first gate reference waveform Vgr1 rises from the time t21, and since the circuit configuration of the gate reference waveform generation unit 13S is applied as the first gate reference waveform generation unit 13A, the first gate reference waveform Vgr1 becomes such a waveform that, after rising at a sharp slope, has a ramp shape in which the decrease rate of voltage is limited, i.e., a second-order differential value of voltage is zero (d²V/dt² =0).

At time t21, the second gate reference waveform generation unit 13B generates the second gate reference waveform Vgr2 on the basis of ON operation of the second gate ON reference signal Sg2. The second gate reference waveform Vgr2 rises from time t22, and since the circuit configuration of the gate reference waveform generation unit 13W is applied as the second gate reference waveform generation unit 13B, the second gate reference waveform Vgr2 partially has such a waveform that a terrace shape in which a first-order differential value of voltage is zero (dV/dt=0) is provided at a part of a ramp shape in which the increase rate of voltage is limited.

At time t21, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the first gate voltage VgeS partially has a ramp shape in which the increase rate of voltage is limited.

At time t23, the second signal amplification unit 14B amplifies the inputted second gate reference waveform Vgr2 and outputs the second gate voltage VgeC. The second gate voltage VgeC reflects the second gate reference waveform Vgr2 and thus the second gate voltage VgeC partially has such a waveform that a terrace shape in which a first-order differential value of voltage is zero (dV/dt=0) is provided at a part of a ramp shape in which the increase rate of voltage is limited.

The first gate voltage Vges and the second gate voltage VgeC are respectively outputted to the first gate terminal Gs and the second gate terminal Gc of the double-gate IGBT 20 provided outside the semiconductor driving device according to modification 2 of embodiment 1.

At time t22 when the first gate voltage Vges becomes equal to or greater than the threshold voltage Vth, the collector current Ic of the double-gate IGBT 20 rises from a zero state that has continued before time t22, and becomes a constant value at time t23 when the second gate voltage VgeC becomes equal to or greater than the threshold voltage Vth.

At time t22 when the first gate voltage VgeS becomes equal to or greater than the threshold voltage Vth, the collector voltage Vce of the double-gate IGBT 20 decreases from a state of VB+Vf that has continued, and becomes ON voltage Von which is a constant value, after time t23.

The sequential operations of each signal when the ON/OFF reference signal Sgd is turned from off to on, i.e., in turn-on operation, are as described above.

### Turn-Off Operation of Semiconductor Driving Device According to Modification 2 of Embodiment 1

Next, sequential operations of each signal when the ON/OFF reference signal Sgd is turned from on to off, i.e., in turn-off operation, will be described.

At time t24, the ON/OFF reference signal Sgd from outside is turned from on to off. That is, the ON/OFF reference signal Sgd is turned from Hi state to Lo state. At time t24, the timing generation unit 12 turns off the first gate ON reference signal Sg1 on the basis of ON operation of the ON/OFF reference signal Sgd. That is, the first gate ON reference signal Sg1 is turned from Hi state to Lo state.

At time t24, the timing generation unit 12 turns off the second gate ON reference signal Sg2 on the basis of OFF operation of the ON/OFF reference signal Sgd.

At time t24, the first gate reference waveform generation unit 13A turns off the first gate reference waveform Vgr1 on the basis of OFF operation of the first gate ON reference signal Sg1. The first gate reference waveform Vgr1 falls from time t24, and since the circuit configuration of the gate reference waveform generation unit 13S is applied as the first gate reference waveform generation unit 13A, the first gate reference waveform Vgr1 becomes such a waveform that, after falling at a sharp slope, has a ramp shape in which the decrease rate of voltage is limited, i.e., a second-order differential value of voltage is zero (d²V/dt²=0).

At time t24, the second gate reference waveform generation unit 13B turns off the second gate reference waveform Vgr2 on the basis of OFF operation of the second gate ON reference signal Sg2. The second gate reference waveform Vgr2 falls from time t24, and since the circuit configuration of the gate reference waveform generation unit 13W is applied as the second gate reference waveform generation unit 13B, the second gate reference waveform Vgr2 becomes such a waveform that a terrace period is provided partway on, i.e., at a part of a ramp shape in which the decrease rate of voltage is limited.

At time t24, the first signal amplification unit 14A amplifies the inputted first gate reference waveform Vgr1 and outputs the first gate voltage VgeS. The first gate voltage VgeS reflects the first gate reference waveform Vgr1 and thus becomes such a waveform that the first gate voltage VgeS partially has a ramp shape in which the decrease rate of voltage is limited.

At time t25, the second signal amplification unit 14B amplifies the inputted second gate reference waveform Vgr2 and outputs the second gate voltage VgeC. The second gate voltage VgeC reflects the second gate reference waveform Vgr2 and thus the second gate voltage VgeC partially has such a waveform that a terrace period is provided partway on, i.e., at a part of a ramp shape in which the decrease rate of voltage is limited.

The first gate voltage VgeS and the second gate voltage VgeC are respectively outputted to the first gate terminal Gs and the second gate terminal Gc of the double-gate IGBT 20 provided outside the semiconductor driving device according to modification 1 of embodiment 1.

At time t25 when the first gate voltage VgeS becomes less than the threshold voltage Vth, the collector current Ic of the double-gate IGBT 20 falls from the constant state that has continued, and becomes zero at time t25 when the second gate voltage VgeC becomes less than the threshold voltage Vth.

At time t25 when the first gate voltage VgeS becomes less than the threshold voltage Vth, the collector voltage Vce of the double-gate IGBT 20 increases from the state of ON voltage Von that has continued, and returns to the constant value VB+Vf at time t26 when the second gate voltage VgeC becomes less than the threshold voltage Vth.

The sequential operations of each signal when the ON/OFF reference signal Sgd is turned from on to off, i.e., in turn-off operation, are as described above.

### Effects of Modification 2 of Embodiment 1

As described above, in the semiconductor driving device according to modification 2 of embodiment 1, the slopes of rising and falling of the first gate ON reference signal Sg1 and the second gate ON reference signal Sg2 are made sharp, whereby conduction performance is increased, thus providing an effect of suppressing dulling of rising and falling of the collector current Ic occurring by driving with a time difference between ramp-shaped waveforms shown in FIG. 7. Meanwhile, along with increase in the collector current Ic, a terrace period is provided at a part of the second gate ON reference signal Sg2, whereby conduction performance is decreased, thus providing an effect of suppressing increase in dIc/dt which is a temporal change rate after rising of the collector current.

### Embodiment 2

### Configuration of Semiconductor Driving Device of Embodiment 2

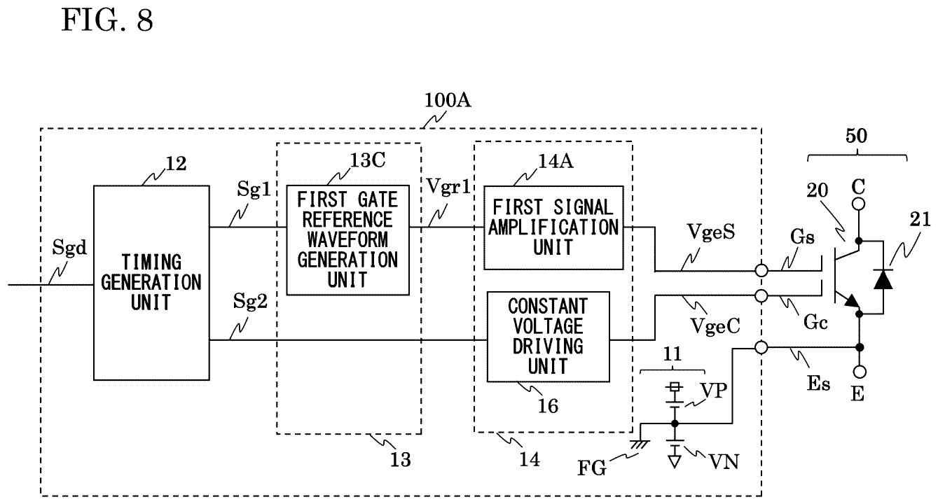

FIG. 8 is a block diagram showing the configuration of a semiconductor driving device 100A according to embodiment 2. The semiconductor driving device 100A according to embodiment 2 includes the timing generation unit 12, the gate reference waveform generation unit 13, the signal amplification unit 14, and the driving voltage generation unit 15. The gate reference waveform generation unit 13 includes a first gate reference waveform generation unit 13C. The signal amplification unit 14 includes the first signal amplification unit 14A and a constant voltage driving unit 16.

A difference between the configuration of the semiconductor driving device 100A according to embodiment 2 and the configuration of the semiconductor driving device 100 according to embodiment 1 is that the gate reference waveform generation unit 13 of the semiconductor driving device 100 according to embodiment 1 is composed of the first gate reference waveform generation unit 13A and the second gate reference waveform generation unit 13B, whereas the gate reference waveform generation unit 13 of the semiconductor driving device 100A according to embodiment 2 is composed of only the first gate reference waveform generation unit 13C.

In the semiconductor driving device 100A according to embodiment 2, regarding two gate voltages which are the first gate voltage VgeS and the second gate reference waveform Vgr2, the first gate voltage VgeS is driven so as to follow the gate reference waveform and the second gate voltage VgeC is driven to be constant voltage. Since the second gate voltage VgeC is driven to be constant voltage, for example, the constant voltage driving unit 16 may be configured as a constant voltage circuit shown in FIG. 12.

### Effects of Embodiment 2

Thus, with the semiconductor driving device 100A according to embodiment 2, deterioration in robustness described above becomes remarkable but the active gate effect is enhanced.

### Embodiment 3

### <Configuration of Power Conversion Device According to Embodiment 3>

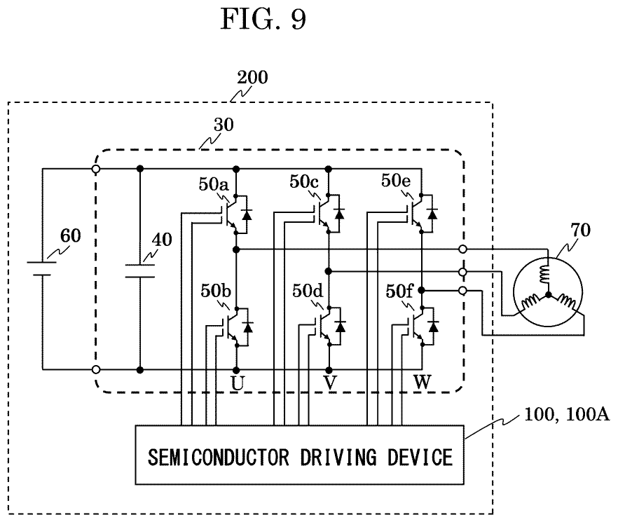

FIG. 9 is a block diagram showing the configuration of a power conversion device 200 according to embodiment 3. As shown in FIG. 9, the power conversion device 200 includes a power converter 30 having a total of six double-gate semiconductor switching elements 50a, 50b, 50c, 50d, 50e, 50f, a smoothing capacitor 40, and either of the semiconductor driving device 100 according to embodiment 1 and the semiconductor driving device 100A according to embodiment 2 for driving the double-gate semiconductor switching elements 50a to 50f in the power converter 30. As an example in which the power conversion device 200 according to embodiment 3 is applied, an inverter device which converts DC power from a DC power supply 60 to AC power and supplies the AC power to an AC motor 70, is shown.

### Effects of Embodiment 3

In the power conversion device 200 according to embodiment 3, the semiconductor driving device 100 according to embodiment 1 or the semiconductor driving device 100A according to embodiment 2 described above is used in signal generation for driving the double-gate semiconductor switching elements 50a to 50f, whereby it becomes possible to provide an inverter device in which energy saving by a loss reduction effect of a double-gate semiconductor switching element and reduction of noise such as radiation noise occurring in the device are both achieved.

As an example of the power conversion device 200 according to embodiment 3, a three-phase inverter device that outputs AC voltage at two levels which are positive and negative has been shown. However, an inverter device that can output multilevel voltage with any number of double-gate semiconductor switching elements connected in series and parallel may be applied.

### Embodiment 4

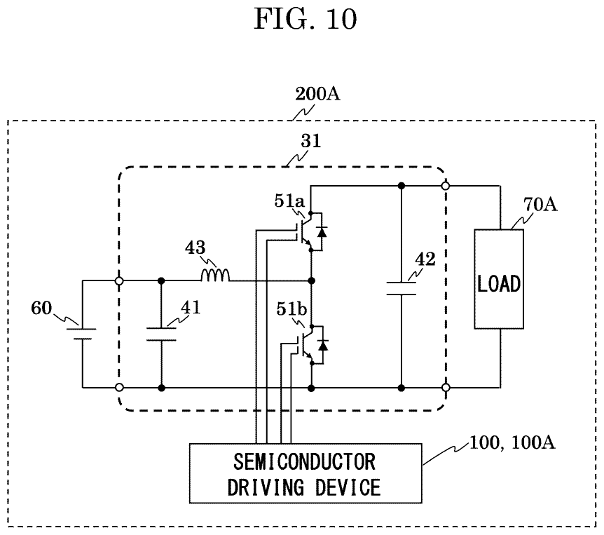

FIG. 10 is a block diagram showing the configuration of a power conversion device 200A according to embodiment 4. Hereinafter, only a difference from the power conversion device 200 according to embodiment 3 will be briefly described.

### Configuration of Power Conversion Device According to Embodiment 4

The power conversion device 200A according to embodiment 4 includes a power converter 31 having a plurality of double-gate semiconductor switching elements 51a and 51b, and either of the semiconductor driving device 100 according to embodiment 1 and the semiconductor driving device 100A according to embodiment 2 for driving the double-gate semiconductor switching elements 51a and 51b in the power converter 31. In a case where the semiconductor driving device 100A according to embodiment 2 is applied, the power conversion device 200A operates as a boost converter device which steps up DC voltage of the DC power supply 60 and supplies the voltage to a DC load 70A.

The power converter 31 includes a leg in which the double-gate semiconductor switching elements 51a and 51b are connected in series, a smoothing capacitor 41 on the input side, a smoothing capacitor 42 on the output side, and a boost reactor 43.

Also in the power conversion device 200A according to embodiment 4, either of the semiconductor driving device 100 according to embodiment 1 and the semiconductor driving device 100A according to embodiment 2 is used, whereby it is possible to provide a boost converter device in which energy saving by a loss reduction effect of a double-gate semiconductor switching element and reduction of noise such as radiation noise occurring from the inverter are both achieved. Further, using the loss reduction effect, the driving frequency of the boost converter device may be improved under an equal loss condition, whereby the size of the boost reactor 43 can be reduced.

As an example of the power conversion device 200A according to embodiment 4, a boost converter device has been shown. However, a buck converter device or a buck-boost converter device in which a boost converter device and a buck converter device are combined, can also be applied in the same manner.

### Embodiment 5

### <Configuration of Power Conversion Device According to Embodiment 5>

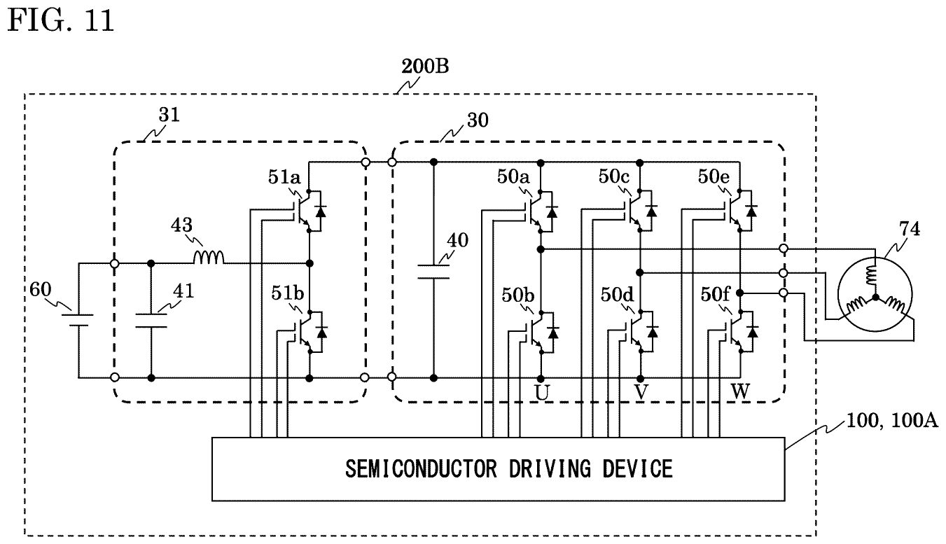

FIG. 11 is a block diagram showing the configuration of a power conversion device 200B according to embodiment 5. Hereinafter, only a difference from embodiment 3 will be briefly described. The power conversion device 200B according to embodiment 5 includes the power converter 30 which forms the power conversion device 200 according to embodiment 3 shown in FIG. 9, the power converter 31 which is connected to the DC side of the power converter 30 and forms the power conversion device 200A according to embodiment 3 shown in FIG. 10, and either of the semiconductor driving devices 100 and 100A according to embodiments 1 and 2 for driving the double-gate semiconductor switching elements 50a to 50f.

The power conversion device 200B steps up DC voltage of the DC power supply 60 by the power converter 31, converts the stepped-up DC power to AC power by the power converter 30, and supplies the AC power to an AC motor 74. The power conversion device 200B operates as a boost inverter system, and is applied to an electric vehicle, for example. The power converter 30 in the power conversion device 200B may be an inverter device that can output multilevel voltage. The power converter 31 in the power conversion device 200B is not limited to a boost converter, and a buck converter device or a buck-boost converter device in which a boost converter device and a buck converter device are combined, can also be applied in the same manner.

In the power conversion device 200B according to

embodiment 5, either of the semiconductor driving devices 100 and 100A according to embodiments 1 and 2 is used, whereby it is possible to provide a boost inverter system in which energy saving by a loss reduction effect of a double-gate semiconductor switching element and reduction of noise such as radiation noise occurring from the inverter device are both achieved. Further, using the loss reduction effect, the driving frequency of the converter may be improved under an equal loss condition, whereby the size of the boost reactor 43 can be reduced.

In all the above embodiments 1 to 5, the case where the multi-gate semiconductor switching element is a double-gate IGBT has been shown as an example. However, as the multi-gate semiconductor switching elements, various multi-gate IGBTs such as a triple-gate IGBT may be applied. Further, some of the multi-gate semiconductor switching elements may be replaced with single-gate IGBTs or single-gate MOSFETs, so as to form hybrid elements. The multi-gate semiconductor switching element may be any of hybrid elements formed by arranging a RC (Reverse-Conducting)-IGBT, an IGBT, and a MOSFET in parallel. The first gate terminal Gs (switching gate) may be formed of a plurality of terminals, and the second gate terminal Gc (control gate) may be formed of a plurality of terminals.

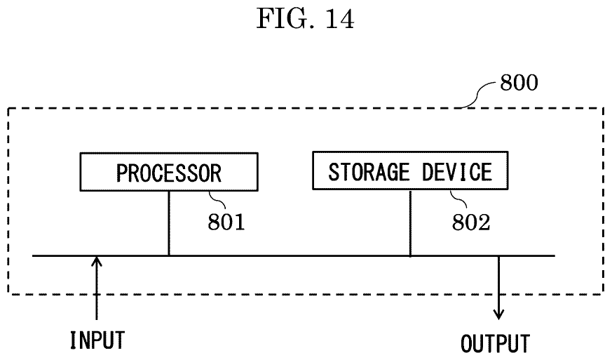

In the configurations of the semiconductor driving devices 100 and 100A and the power conversion devices 200, 200A, and 200B according to the above embodiments 1 to 5, parts of the semiconductor driving devices 100 and 100A and the power conversion devices 200, 200A, and 200B have been described as function blocks. An example of the configuration of hardware for storing the semiconductor driving device 100, 100A and the power conversion device 200, 200A, 200B is shown in FIG. 14. Hardware 800 is composed of a processor 801 and a storage device 802. Although not shown, the storage device 802 is provided with a volatile storage device such as a random access memory and a nonvolatile auxiliary storage device such as a flash memory.

Instead of the flash memory, an auxiliary storage device of a hard disk may be provided. The processor 801 executes a program inputted from the storage device 802. In this case, the program is inputted from the auxiliary storage device to the processor 801 via the volatile storage device. The processor 801 may output data such as a calculation result to the volatile storage device of the storage device 802, or may store such data into the auxiliary storage device via the volatile storage device.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

12 timing generation unit
13, 13P, 13Q, 13R, 13S, 13T, 13U, 13V, 13W gate reference waveform generation unit
13A, 13C first gate reference waveform generation unit
13B second gate reference waveform generation unit
14, 14P, 14Q, 14R, 14S signal amplification unit
14A first signal amplification unit
14B second signal amplification unit
15 driving voltage generation unit
16 constant voltage driving unit
20 double-gate IGBT
21 diode
25 IGBT module
30, 31 power converter
40, 41, 42 smoothing capacitor
43 boost reactor
50a, 50b, 50c, 50d, 50e, 50f, 51a, 51b double-gate semiconductor switching element
60 DC power supply
70, 74 AC motor
70A load
100, 100A semiconductor driving device
200, 200A, 200B power conversion device
800 hardware
801 processor
802 storage device
C1, C2, C3, C4 capacitor
D2 diode
DS1, DS2, DS3, DS4, DS5, DS6 constant current diode
DZ1, DZ2, DZ3 zener diode
Gs first gate terminal
Gc second gate terminal
OP1, OP2 operational amplifier
Q1, Q3 NPN transistor
Q2, Q4 PNP transistor
R2, R11, R12 gate resistor
R3, R4, R5, R6, R7, R8, R9 resistor
R10 base resistor
Sgd ON/OFF reference signal
Sg1 first gate ON reference signal
Sg2 second gate ON reference signal
Vce collector voltage
Vge gate voltage
Vges first gate voltage
VgeC second gate voltage
Vgr1 first gate reference waveform
Vgr2 second gate reference waveform
Von ON voltage
Vth threshold voltage

1. A semiconductor driving device for driving a multi-gate semiconductor switching element having a plurality of gate terminals, the semiconductor driving device comprising:
a timing generator which turns on/off gate ON reference signals respectively for the plurality of gate terminals on the basis of an ON/OFF reference signal from outside;
a gate reference waveform generator which generates a first gate reference waveform corresponding to at least one first gate terminal and a second gate reference waveform corresponding to at least one second gate terminal, among the plurality of gate terminals, on the basis of on/off of the gate ON reference signals, and controls one or both of the first gate reference waveform and the second gate reference waveform in one or both of shifting from a non-conductive state to a conductive state of the multi-gate semiconductor switching element and shifting from a conductive state to a non-conductive state of the multi-gate semiconductor switching element; and
a signal amplifier which receives, as an input waveform, one or both of the first gate reference waveform and the second gate reference waveform, and amplifies the input waveform so that an output waveform follows the input waveform.

2. (canceled)

3. The semiconductor driving device according to claim 1, wherein
in shifting from a non-conductive state to a conductive state of the multi-gate semiconductor switching element, the gate reference waveform generator performs control so that one or both of a second-order differential value of the first gate reference waveform and a second-order differential value of the second gate reference waveform become not greater than zero, and in shifting from a conductive state to a non-conductive state of the multi-gate semiconductor switching element, the gate reference waveform generator performs control so that one or both of a second-order differential value of the first gate reference waveform and a second-order differential value of the second gate reference waveform become not less than zero.

4. (canceled)

5. The semiconductor driving device according to claim 1, wherein
in shifting from a non-conductive state to a conductive state of the multi-gate semiconductor switching element, the gate reference waveform generator performs control so that one or both of the first gate reference waveform and the second gate reference waveform include a part where a second-order differential value thereof is less than zero and a part where a second-order differential value thereof is zero, and in shifting from a conductive state to a non-conductive state of the multi-gate semiconductor switching element. the gate reference waveform generator performs control so that one or both of the first gate reference waveform and the second gate reference waveform include a part where a second-order differential value thereof is greater than zero and a part where a second-order differential value thereof is zero.

6. (canceled)

7. The semiconductor driving device according to claim 1, wherein
in shifting from a non-conductive state to a conductive state of the multi-gate semiconductor switching element, the gate reference waveform generator performs control so that one or both of the first gate reference waveform and the second gate reference waveform include a part where a second-order differential value thereof is less than zero and a part where a first-order differential value thereof is zero, and in shifting from a conductive state to a non-conductive state of the multi-gate semiconductor switching element. the gate reference waveform generator performs control so that one or both of the first gate reference waveform and the second gate reference waveform include a part where a second-order differential value thereof is greater than zero and a part where a first-order differential value thereof is zero.

8. (canceled)

9. The semiconductor driving device according to claim 1, wherein
voltage not less than threshold voltage is applied to at least the first gate terminal of the multi-gate semiconductor switching element temporally prior to other gate terminals including the second gate terminal.

10. The semiconductor driving device according to claim 1, wherein
voltage less than threshold voltage is applied to at least the first gate terminal of the multi-gate semiconductor switching element temporally prior to other gate terminals including the second gate terminal.

11. The semiconductor driving device according to claim 1, wherein
the first gate reference waveform and the second gate reference waveform are identical waveforms with a predetermined time difference therebetween.

12. The semiconductor driving device according to claim 1, wherein
at least one of the first gate reference waveform and the second gate reference waveform partially includes a charge voltage shape or a discharge voltage shape formed by a capacitor and a resistor.

13. The semiconductor driving device according to claim 1, wherein
the gate reference waveform generator performs control so that at least one of the first gate reference waveform and the second gate reference waveform in shifting from a non-conductive state to a conductive state of the multi-gate semiconductor switching element partially includes such a shape that a first-order differential value of the gate reference waveform discontinuously decreases, and at least one of the first gate reference waveform and the second gate reference waveform in shifting from a conductive state to a non-conductive state of the multi-gate semiconductor switching element partially includes such a shape that a first-order differential value of the gate reference waveform discontinuously increases.

14. (canceled)

15. The semiconductor driving device according to claim 3, wherein
the signal amplifier includes one or both of a complementary emitter follower circuit and a complementary source follower circuit.

16. The semiconductor driving device according to claim 1, wherein
the gate reference waveform generator includes at least one operational amplifier.

17. The semiconductor driving device according to claim 1, wherein
the multi-gate semiconductor switching element is any of hybrid elements formed by arranging a multi-gate IGBT, an RC-IGBT, an IGBT, and a MOSFET in parallel.

18. A power conversion device comprising:
a device which has a multi-gate semiconductor switching element as a semiconductor switching element and which is one of an inverter device which converts DC power to AC power, a boost converter device which steps up voltage of DC power, a buck converter device which steps down voltage of DC power, an AC-DC converter device which converts AC power to DC power, a boost inverter device which includes the boost converter device and the inverter device, and a buck inverter device which includes the buck converter device and the inverter device; and
the semiconductor driving device according to claim 1, which drives the multi-gate semiconductor switching element.
